(19) United States
(12) Patent Application Publication
(10) Pub. No.: US 2024/0178099 A1
(43) Pub. Date: May 30, 2024

(54) POWER MODULE AND METHOD FOR PRODUCING SAME

(71) Applicant: AMOSENSE CO., LTD., Cheonan-si, Chungcheongnam-do (KR)

(72) Inventor: Jihyung LEE, Cheonan-si (KR)

(73) Assignee: AMOSENSE CO., LTD., Cheonan-si, Chungcheongnam-do (KR)

(21) Appl. No.: 18/283,713

(22) PCT Filed: Mar. 18, 2022
(86) PCT No.: PCT/KR2022/003794

§ 371 Date: Sep. 22, 2023

(30) Foreign Application Priority Data
Mar. 25, 2021 (KR) 10-2021-0038829

(51) Int. Cl. H01L 23/373; H01L 23/00

(52) U.S. Cl. CPC H01L 23/3735; H01L 24/16; H01L 24/32; H01L 24/48; H01L 24/73; H01L 2224/16225; H01L 2224/32225; H01L 2224/48225; H01L 2224/73253; H01L 2224/73265

(57) ABSTRACT

The present invention relates to a power module and a method for producing same, in which the bottom electrode layer of a ceramic substrate is inserted into recesses of a base plate, and with the ceramic substrate stacked on the base plate, adhesion via brazing is carried out, thus improving adhesion reliability, preventing flexure, and provides highly efficient heat dissipation.

### TECHNICAL FIELD

The present disclosure relates to a power module and a method for producing the same, and more particularly, to a power module and a method for producing the same, which can improve a bonding reliability of a ceramic substrate and a base plate.

### BACKGROUND ART

Generally, in a power module, a base plate is formed in a rectangular plate shape, and is formed of an aluminum or copper material. Such a base plate may be bonded onto a lower surface of a ceramic substrate, and may be used as a heat sink. The base plate may be bonded by soldering onto the lower surface of the ceramic substrate so as to be good for heat dissipation.

However, since the base plate in the related art has a thermal expansion coefficient equal to or larger than 17.8 ppm/K, a flexure may occur due to a difference between thermal expansion coefficients of the base plate and the ceramic substrate during bonding with the ceramic substrate. Further, solder paste may melt at a high temperature to cause the flexure or defect of the base plate.

As solution schemes for this, the ceramic substrate and the base plate are bonded at a temperature equal to or lower than 250° C. with AlSiC or similar materials. According to the bonding structure of the base plate and the ceramic substrate in the related art, the base plate may be made of a CuMo or Ni—Au material, and is bonded by soldering onto the ceramic substrate through the medium of a solder preform. In this case, as the solder preform, SAC305 made of a composition including Sn, Ag, and Cu is used, and the soldering temperature is 230° C. to 350° C.

However, the bonding structure of the base plate and the ceramic substrate in the related art may cause an increase of a process cost due to the solder paste and the solder preform used for the bonding and processes of vacuum bonding equipment and the like, and may cause bonding reliability and yield problems.

### SUMMARY OF INVENTION

### Technical Problem

An object of the present disclosure is to provide a power module and a method for producing the same, which can improve bonding reliability by preventing a flexure or porosity defect that causes a problem during bonding of a ceramic substrate and a base plate, can achieve high-reliability bonding for various base plates, and can achieve process simplification and saving of process costs.

### Solution to Problem

In order to achieve the above object, a power module according to an embodiment of the present disclosure may include: a ceramic substrate; and a base plate bonded onto a lower part of the ceramic substrate, wherein the ceramic substrate includes: a ceramic base material; an upper electrode layer formed on an upper surface of the ceramic base material; and a lower electrode layer formed on a lower surface of the ceramic base material and separated into a plurality of areas, and wherein the base plate has a plurality of recess grooves formed thereon to correspond to the lower electrode layer, and the lower electrode layer is inserted into the recess grooves.

The lower electrode layer may be separated into the plurality of areas by a space formed by etching a part of the lower electrode layer in a thickness direction. As such a space is formed on the lower electrode layer, a volume ratio that is obtained by dividing a total volume of the upper electrode layer by a total volume of the lower electrode layer may be adjusted to be in a range of 0.9 to 1.1.

Further, if thicknesses of the upper electrode layer and the lower electrode layer are equal to each other, the space may be formed so that an area ratio that is obtained by dividing a total area of the upper electrode layer by a total area of the lower electrode layer is in a range of 0.9 to 1.1.

A brazing filler may be disposed between the lower electrode layer and the recess grooves, and may braze the ceramic substrate and the base plate.

The recess groove of the base plate may be formed with a thickness that is equal to a sum of thicknesses of the lower electrode layer and the brazing filler.

A method for producing a power module according to an embodiment may include: preparing an upper electrode layer and a lower electrode layer on upper and lower surfaces of a ceramic base material, and preparing a ceramic substrate on which the lower electrode layer is separated into a plurality of areas; preparing a base plate having a recess groove formed thereon to correspond to the lower electrode layer; inserting the lower electrode layer into the recess groove; and bonding the ceramic substrate on the base plate in a laminated state.

The preparing of the ceramic substrate may include forming a space that is separated into the plurality of areas by etching a part of the lower electrode layer in a thickness direction.

The forming of the space that is separated into the plurality of areas may form the space so that a volume ratio that is obtained by dividing a total volume of the upper electrode layer by a total volume of the lower electrode layer is in a range of 0.9 to 1.1.

Further, the forming of the space that is separated into the plurality of areas may form the space so that an area ratio that is obtained by dividing a total area of the upper electrode layer by a total area of the lower electrode layer is in a range of 0.9 to 1.1 in case that thicknesses of the upper electrode layer and the lower electrode layer are equal to each other.

In the preparing of the base plate, the base plate may be annealed to remove a thermal stress therefrom.

The preparing of the base plate may include disposing a brazing filler onto the recess groove.

In the preparing of the base plate, the recess groove may be formed by etching the base plate in a thickness direction, and a depth of the recess groove may be equal to a sum of thicknesses of the lower electrode layer and the brazing filler.

The disposing of the brazing filler may dispose the brazing filler having a thickness that is equal to or larger than 5 μm and equal to or smaller than 100 μm onto the recess groove by any one method of paste application, foil attachment, and P-filler.

The bonding of the ceramic substrate on the base plate in the laminated state may include brazing the brazing filler through melting.

The brazing may be performed at 780° C. to 900° C., and top weighting or pressurization may be carried out during the brazing.

### Advantageous Effects of Invention

According to the present disclosure, since the ceramic substrate is brazed onto the base plate in the laminated state through insertion of the lower electrode layer into the recess groove, the bonding reliability is heightened, the flexure can be prevented, and the heat dissipation effect is heightened.

Further, according to the present disclosure, since the brazing is performed in a state where the lower electrode layer and the recess groove are fitted in size, the space in which bubbles occur can be removed during injection of insulation gel, and the porosity defect can be prevented.

Further, according to the present disclosure, since the space is formed through etching of a part of the lower electrode layer in the thickness direction, the volume ratio and the area ratio of the upper electrode layer and the lower electrode layer can be controlled to be within the specific range, and thus the flexure phenomenon occurring due to the volume difference can be suppressed.

Further, according to the present disclosure, since the brazing is performed through melting of the brazing filler after the thermal stress and the thermal strain are removed in advance through heat treatment of the base plate, the bonding reliability can be improved.

### BRIEF DESCRIPTION OF DRAWINGS

FIG. 1 is an exploded perspective view illustrating a bonding structure of a ceramic substrate and a base plate and a ceramic substrate for a power module according to an embodiment of the present disclosure.

FIG. 2 is an exploded cross-sectional view illustrating a bonding structure of a ceramic substrate and a base plate for a power module according to an embodiment of the present disclosure.

FIG. 3 is a view illustrating upper and lower surfaces of a ceramic substrate according to an embodiment of the present disclosure.

FIG. 4 is a cross-sectional view illustrating a bonding structure of a ceramic substrate and a base plate for a power module according to an embodiment of the present disclosure.

FIG. 5 is a cross-sectional view illustrating an example of a power module provided with a SiC chip.

FIG. 6 is a cross-sectional view illustrating an example of a power module provided with a GaN chip.

FIG. 7 is a flowchart illustrating a method for producing a power module according to an embodiment of the present disclosure.

### DESCRIPTION OF EMBODIMENTS

Hereinafter, embodiments of the present disclosure will be described in detail with reference to the accompanying drawings.

The present disclosure is featured on a bonding structure of a base plate and a ceramic substrate among constitutions included in a power module, and explanation will be made around this.

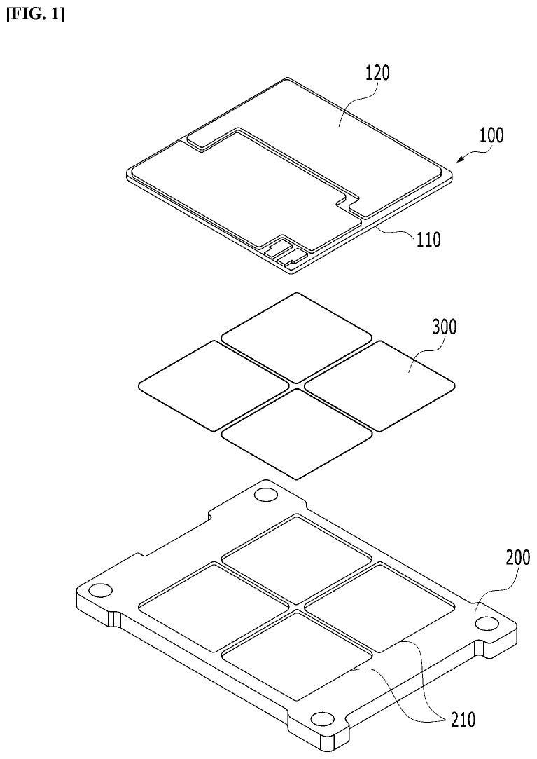

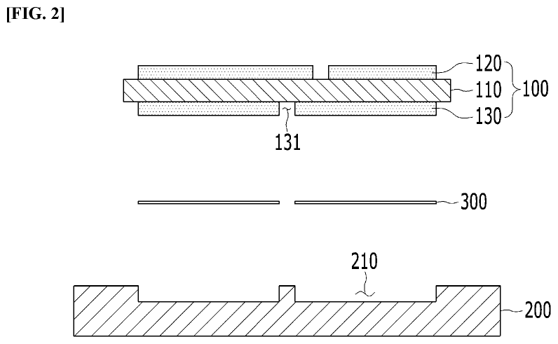

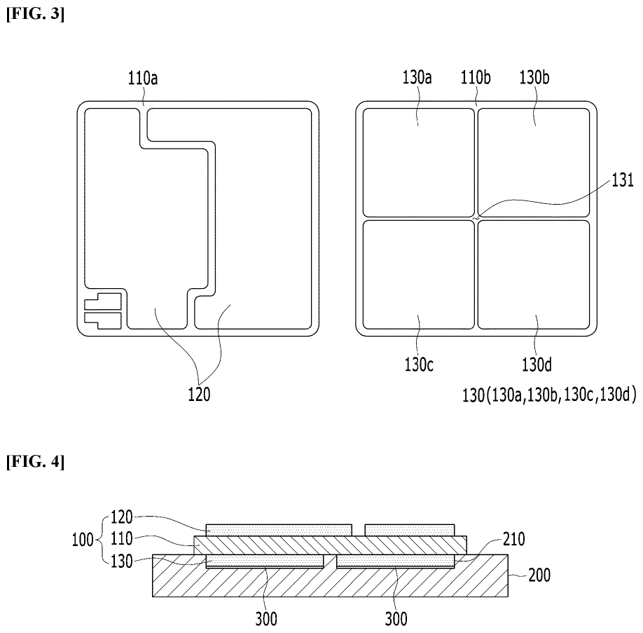

FIG. 1 is an exploded perspective view illustrating a bonding structure of a ceramic substrate and a base plate and a ceramic substrate for a power module according to an embodiment of the present disclosure, and FIG. 2 is an exploded cross-sectional view illustrating a bonding structure of a ceramic substrate and a base plate for a power module according to an embodiment of the present disclosure. FIG. 3 is a view illustrating upper and lower surfaces of a ceramic substrate according to an embodiment of the present disclosure, and FIG. 4 is a cross-sectional view illustrating a bonding structure of a ceramic substrate and a base plate for a power module according to an embodiment of the present disclosure.

As illustrated in FIGS. 1 and 2, a power module according to an embodiment of the present disclosure may be provided with a ceramic substrate 100, and a base plate 200 bonded onto a lower part of the ceramic substrate 100.

The ceramic substrate 100 may be an active metal brazing (AMB) substrate provided with a ceramic base material 110 and upper and lower electrode layers 120 and 130 on upper and lower surfaces of the ceramic base material 110. In an embodiment, the AMB substrate is exemplarily explained, but a direct bonded copper (DBC) substrate, a thick printing copper (TPC) substrate, or a direct brazed aluminum (DBA) substrate may also be applied. The AMB substrate is most suitable for the durability and heat dissipation efficiency against heat that is generated from the semiconductor chip.

As an example, the ceramic base material 110 of the ceramic substrate 100 may be any one of alumina (Al₂O₃), AIN, SiN, and Si₃N₄.

As illustrated in FIG. 3, the upper electrode layer 120 may be formed as an electrode pattern on an upper surface 110a of the ceramic substrate 110. For example, the upper electrode layer 120 may be provided in the form of a metal foil, may be brazed onto the upper surface 110a of the ceramic base material 110, and thereafter, may be formed as an electrode pattern for mounting the semiconductor chip and an electrode pattern for mounting a driving element through etching. As an example, the metal electrode layer 120 may be made of one of Cu, a Cu alloy, OFC, EPT Cu, and Al. The OFC is an oxygen-free copper.

The lower electrode layer 130 may be formed on a lower surface 110b of the ceramic base material 110, and may be separated into a plurality of areas 130a, 130b, 130c, and 130d. For example, the lower electrode layer 130 may be provided in the form of a metal foil composed of one of Cu, a Cu alloy, OFC, EPT Cu, and Al, may be brazed onto a lower surface 110b of the ceramic substrate 110, and thereafter, may be separated into the plurality of areas 130a, 130b, 130c, and 130d by a space 131 formed through etching of a part thereof in a thickness direction.

In case that the lower electrode layer 130 is formed as a flat plate so as to increase a bonding area with the base plate 200 without the space 131, it has a large volume difference in comparison to the total volume of the upper electrode layer 120 formed as an electrode pattern, and thus the ceramic substrate 100 is flexed in a high-temperature environment. According to empirical data, the volume ratio obtained by dividing the total volume of the upper electrode layer 120 formed as the electrode pattern by the total volume of the lower electrode layer 130 that is in the form of a flat plate is about 0.76, and in this case, the degree of flexure exceeds 0.4%, so that the ceramic substrate 100 can only be discarded as defective. Such a defect occurrence rate accounts for a relatively large share of total production to cause the problem of a continuous production loss.

In order to solve the above problem, according to the present disclosure, the flexure phenomenon occurring due to the volume difference can be suppressed by controlling the volume ratio and the area ratio of the upper electrode layer 120 and the lower electrode layer 130 to be within a specific range through the space 131.

Since the upper electrode layer 120 of the ceramic substrate 100 is formed as the electrode pattern on which the semiconductor chip is mounted, it is often designed with fixed form, thickness, and length. Thus, according to the present disclosure, the total volume and area of the lower electrode layer 130 can be adjusted by forming the space 131 through etching of a part of the lower electrode layer 130 in the thickness direction and separating the lower electrode layer 130 into the plurality of areas 130a, 130b, 130c, and 130d through the space 131. That is, in case that the space 131 is formed on the lower electrode layer 130 and the total volume and area of the lower electrode layer 130 is reduced, the volume ratio and the area ratio of the upper electrode layer 120 and the lower electrode layer 130 can be adjusted to be within the range of 0.9 to 1.1.

Specifically, it is preferable that the ceramic substrate 100 is designed so that the volume ratio obtained by dividing the total volume of the upper electrode layer 120 by the total volume of the lower electrode layer 130 is within the range of 0.9 to 1.1, and in order to minimize the flexure, it is more preferable that the ceramic substrate 100 is designed so that the volume ratio is close to 1.0.

The total volume is calculated as a product of the total area and the thickness, and if the upper and lower electrode layers 120 and 130 have the same thickness, the volume ratio can be made to be within the range of 0.9 to 1.1 through adjustment of the area according to the thickness.

As an example, the thicknesses of the upper electrode layer 120 and the lower electrode layer 130 may be equal to each other as 0.3 T or 0.5 T. As described above, in case that the thicknesses of the upper electrode layer 120 and the lower electrode layer 130 are equal to each other, it is preferable that the ceramic substrate 100 is designed so that the area ratio obtained by dividing the total area of the upper electrode layer 120 by the total area of the lower electrode layer 130 is within the range of 0.9 to 1.1, and in order to minimize the flexure, it is more preferable that the ceramic substrate 100 is designed so that the area ratio is close to 1.0. That is, if it is designed that the area ratio is within the range of 0.9 to 1.1 in case that the thicknesses are equal to each other, the volume ratio can also be adjusted to be within the range of 0.9 to 1.1.

Meanwhile, the lower electrode layer 130 may be separated into various shapes by the space 131. For example, as shown in FIG. 3, the lower electrode layer 130 may be separated into four areas 130a, 130b, 130c, and 130d each having a rectangular cross-section and the same area by the space 131 etched in a cross shape. In addition, the lower electrode layer 130 may be separated into a plurality of areas having various shapes, such as a triangle, by the space formed through the etching.

As illustrated in FIG. 4, the base plate 200 is bonded onto a lower part of the ceramic substrate 100, and may be used to dissipate heat that is generated from the semiconductor chip mounted on the ceramic substrate 100. The base plate 200 may be formed in a rectangular plate shape having a predetermined thickness. Further, the base plate 200 may be designed in the form in which the flexure is minimized based on a flexure change amount that is derived through calculation of the thermal expansion coefficient and the bonding area or volume in advance.

The base plate 200 is formed of a material that can heighten the heat dissipation efficiency. As an example, the base plate 200 may be composed of at least one of Cu, Al, Ni—Au, AlSiC, CuMo, CuW, Cu/CuMo/Cu, Cu/Mo/Cu, and Cu/W/Cu, or a composite material thereof. The materials of Cu, Al, AlSiC, CuMo, CuW, Cu/CuMo/Cu, Cu/Mo/Cu, and Cu/W/Cu have prominent thermal conductivity, and the materials of AlSiC, CuMo, CuW, Cu/CuMo/Cu, Cu/Mo/Cu, and Cu/W/Cu have a low thermal expansion coefficient, and thus can minimize the flexure occurrence when being bonded onto the ceramic substrate 100.

In case of being formed as a 3-layer bonding metal sheet structure of Cu/CuMo/Cu or AlSiC, the base plate 200 may have the prominent bonding characteristic in the bonding with the ceramic substrate 100, and may have the thermal characteristics, that is, the thermal expansion coefficient of 6.8 to 12 ppm/K and the thermal conductivity of 220 to 280 W/m·K.

The base plate 200 may have a recess groove 210 recessed downward and formed on an upper surface of the base plate 200. The recess groove 210 may be formed with the shape and the number corresponding to the lower electrode layer 130 separated into the plurality of areas 130a, 130b, 130c, and 130d. In an embodiment, the recess groove 210 may be formed as four grooves each having a rectangular cross-section and the same area to correspond to the lower electrode layer 130.

In the recess groove 210, a brazing filler 300 for bonding the ceramic substrate 100 and the base plate 200 may be disposed. Here, the recess groove 210 may be formed with a depth that is equal to a sum of thicknesses of the lower electrode layer 130 and the brazing filler 300. That is, since the brazing filler 300 and the lower electrode layer 130 can be accommodated to fit the size of the recess groove 210, no space is made between the lower electrode layer 130 and the base plate 200, and thus the bubble occurrence can be prevented. As an example, in case that the thickness of the lower electrode layer 130 is 0.5 T, and the thickness of the brazing filler 300 is 0.03 T, the depth of the recess groove 210 may be 0.53 T.

The brazing filler 300 is to secure the bonding characteristic between the ceramic substrate 100 and the base plate 200. In case that the ceramic substrate 100 and the base plate 200 are soldered, a gap may occur due to a flexure occurrence at a high temperature, and thus bonding reliability is lowered.

In contrast, according to the present disclosure, since the brazing filler 300 is disposed between the lower electrode layer 130 and the recess groove 210, the lower electrode layer 130 is inserted into the recess groove 210, and the brazing is performed in a state where four sides of the lower electrode layer 130 come in contact with an inner side of the recess groove 210 in all, the contact area is increased, and thus the bonding force is better. Accordingly, the flexure of the ceramic substrate 100 can be suppressed by the base plate 200, and thus the heat dissipation effect is heightened.

Further, since the lower electrode layer 130 is inserted into the recess groove 210, an accurate mutual alignment of the ceramic substrate 100 and the base plate 200 can be easily made, and the bonding accuracy can be improved since there is no problem of getting out of their positions in a high-temperature environment during brazing.

The brazing filler 300 may be composed of a material including at least one of Ag, Cu, AgCu, and AgCuTi. Here, the Ag and Cu have a high thermal conductivity, and thus heighten not only the bonding force but also the heat dissipation efficiency by facilitating heat transfer between the ceramic substrate 100 and the base plate 200. Further, Ti has a good wettability, and thus facilitates attachment of Ag and Cu onto an inner side of the recess groove 210.

The brazing filler 300 may be formed as a thin film of a multilayer structure. The thin film of the multilayer structure is to heighten the bonding force by making up for the poor performance. As an example, the brazing filler 300 may be composed of a two-layer structure including an Ag layer and a Cu layer formed on the Ag layer. Further, the brazing filler 300 may be composed of a three-layer structure including a Ti layer, an Ag layer formed on the Ti layer, and a Cu layer formed on the Ag layer. After the brazing filler 300 is used for the brazing of the ceramic substrate 100 and the base plate 200, the boundary of the multilayer structure may become ambiguous.

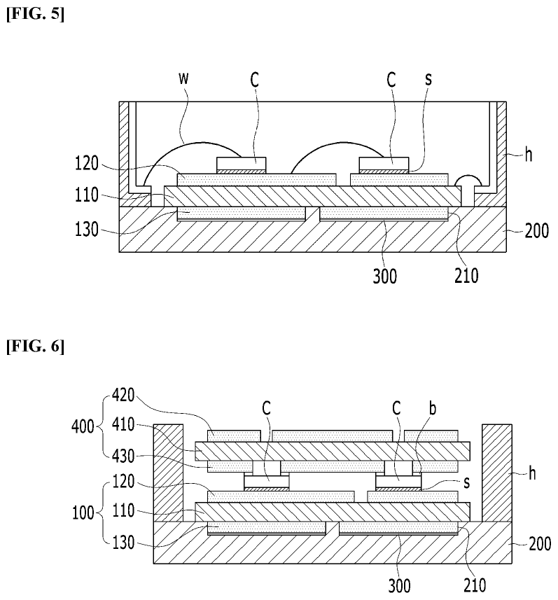

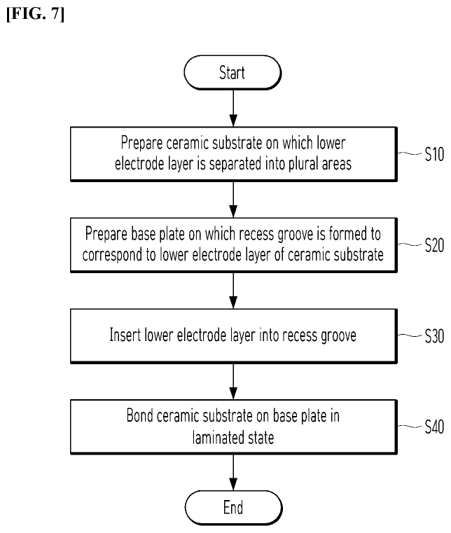

FIG. 5 is a cross-sectional view illustrating an example of a power module provided with a SiC chip, and FIG. 6 is a cross-sectional view illustrating an example of a power module provided with a GaN chip.

As illustrated in FIGS. 5 and 6, in a power module, a semiconductor chip C may be mounted on an upper electrode layer 120 of a ceramic substrate 100. The semiconductor chip C may be provided with any one of an Si chip, a metal oxide semiconductor field effect transistor (MOSFET), an insulated gate bipolar transistor (IGBT), a junction field effect transistor (JFET), and a high electric mobility transistor (HEMT) in addition to the SiC chip and the GaN chip illustrated in FIGS. 5 and 6.

As illustrated in FIG. 5, a lower part of the SiC chip C may be bonded onto an upper electrode layer 120 of the ceramic substrate 100 through a solder layer s, and an upper part of the SiC chip C may be electrically connected to an outside by a bonding wire w.

As illustrated in FIG. 6, a lower part of the GaN chip C may be bonded onto an upper electrode layer 120 of a lower ceramic substrate 100 through a solder layer s, and an upper part of the GaN chip C may be bonded onto an upper ceramic substrate 400 by a bonding layer b in the form of a flip chip. The upper ceramic substrate 400 may be provided with the upper electrode layer 420 on an upper surface of the ceramic base material 410 and a lower electrode layer 430 on a lower surface of the ceramic base material 410, and the upper part of the GaN chip C may be bonded onto the lower surface of the lower electrode layer 430 in the form of a flip chip.

As illustrated in FIGS. 5 and 6, since the semiconductor chip C is mounted on the power module, an insulation gel material, such as silicone or epoxy, may be injected into an inner space of a housing h for the purpose of protection of the semiconductor chip, vibration relief, and insulation. In this case, if there is a space between the lower electrode layer 130 of the ceramic substrate 100 and the base plate 200, bubbles occur, and thus the porosity defect occurs. According to the present disclosure, since the brazing is performed in a state where the lower electrode layer 130 and the recess groove 210 are fitted in size, the space in which bubbles occur can be removed, and through this, the porosity defect can be prevented. In addition, since the lower electrode layer 130 is inserted into the recess groove 210, the total module thickness can be reduced.

FIG. 7 is a flowchart illustrating a method for producing a power module according to an embodiment of the present disclosure.

As illustrated in FIG. 7, a method for producing a power module according to an embodiment of the present disclosure may include: preparing an upper electrode layer 120 and a lower electrode layer 130 on upper and lower surfaces of a ceramic base material 110 and preparing a ceramic substrate 100 on which the lower electrode layer 130 is separated into a plurality of areas 130a, 130b, 130c, and 130d (S10); preparing a base plate 200 having a recess groove 210 formed thereon to correspond to the lower electrode layer 130 (S20); inserting the lower electrode layer 130 into the recess groove 210 (S30); and bonding the ceramic substrate 100 on the base plate 200 in a laminated state (S40).

In the preparing of the ceramic substrate 100 (S10), the ceramic substrate 100 may be an active metal brazing (AMB) substrate provided with the upper and lower electrode layers 120 and 130 on the upper and lower surfaces of the ceramic base material 110.

The preparing of the ceramic substrate 100 (S10) may include forming a space 131 that is separated into the plurality of areas by etching a part of the lower electrode layer 130 in a thickness direction. Since the space 131 is formed in the lower electrode layer 130, the lower electrode layer 130 can be separated into the plurality of areas 130a, 130b, 130c, and 130d.

The forming of the space 131 that is separated into the plurality of areas may form the space 131 so that a volume ratio that is obtained by dividing a total volume of the upper electrode layer 120 by a total volume of the lower electrode layer 130 becomes 0.9 to 1.1.

Further, the forming of the space 131 that is separated into the plurality of areas may form the space 131 so that an area ratio that is obtained by dividing a total area of the upper electrode layer 120 by a total area of the lower electrode layer 130 becomes 0.9 to 1.1 in case that thicknesses of the upper electrode layer 120 and the lower electrode layer 130 are equal to each other.

As described above, according to the present disclosure, since the space 131 is formed by etching a part of the lower electrode layer 130 in the thickness direction, the total volume and area of the lower electrode layer 130 can be adjusted, and through this, the volume ratio and the area ratio of the upper electrode layer 120 and the lower electrode layer 130 can be adjusted to be within the range of 0.9 to 1.1. Since the upper electrode layer 120 is formed as an electrode pattern on which the semiconductor chip is mounted, the flexure of the ceramic substrate 100 occurs in the high-temperature environment in case that the lower electrode layer 130 is formed as a flat plate and the volume difference becomes large. Thus, according to the present disclosure, the flexure phenomenon that occurs due to the volume difference can be suppressed by controlling the volume ratio and the area ratio of the upper electrode layer 120 and the lower electrode layer 130 to be in the specific range through the space 131 formed through etching of a part of the lower electrode layer 130 in the thickness direction.

In the preparing of the base plate 200 (S20), the recess groove 210 corresponding to the lower electrode layer 130 may be formed on the base plate 200. The base plate 200 is prepared as a plate that is composed of at least one of Cu, Al, Ni—Au, AlSiC, CuMo, CuW, Cu/CuMo/Cu, Cu/Mo/Cu, and Cu/W/Cu, or a composite material thereof. Preferably, the base plate 200 is prepared as a plate that is composed of at least one of AlSiC, CuMo, CuW, Cu/CuMo/Cu, Cu/Mo/Cu, and Cu/W/Cu, or a composite material thereof. The materials of AlSiC, CuMo, CuW, Cu/CuMo/Cu, Cu/Mo/Cu, and Cu/W/Cu have a low thermal expansion coefficient in comparison to Cu and Al, and thus can minimize the flexure phenomenon that occurs due to the difference in thermal expansion coefficients at a high temperature.

The thickness of the base plate 200 may be in the range of 1.0 mm to 3.0 mm. Preferably, the thickness of the base plate 200 that is equal to or larger than 2.0 mm is good for heat dissipation, so that the flexure phenomenon can be minimized.

Further, in the preparing of the base plate 200 (S20), the base plate 200 may be annealed to remove a thermal stress therefrom. Such annealing is to remove the thermal stress of the base plate 200 in advance, and may be performed in an electric furnace or a gas furnace at a temperature of 600° C. to 750° C. If the thermal stress given to the base plate 200 is removed in advance as described above, the thermal stress that is generated through the thermal expansion and thermal contraction in the process of brazing the ceramic substrate 100 and the base plate 200 is relieved, and thus the bonding reliability can be improved. Further, since the bonding region is not damaged, the heat transfer effect becomes superior, and thus the heat dissipation characteristic can be improved.

The preparing of the base plate 200 (S20) may include disposing the brazing filler 300 onto the recess groove 210. The brazing filler 300 is to bond the ceramic substrate 100 and the base plate 200, and after the brazing filler 300 is disposed onto the recess groove 210, the lower electrode layer 130 may be inserted into the recess groove 210.

In the preparing of the base plate 200 (S20), the recess groove 210 may be formed by etching the base plate 200 in the thickness direction. In this case, the recess groove 210 may be formed with a depth that is equal to the sum of the thicknesses of the lower electrode layer 130 and the brazing filler 300. That is, the recess groove 210 may be formed to accommodate the brazing filler 300 and the lower electrode layer 130 to fit in size.

The disposing of the brazing filler 300 may dispose the brazing filler 300 having a thickness that is equal to or larger than 5 μm and equal to or smaller than 100 μm onto the recess groove 210 by any one method of paste application, foil attachment, and P-filler. The brazing filler 300 may be made of a material including at least one of Ag, Cu, AgCu, and AgCuTi.

The bonding of the ceramic substrate 100 on the base plate 200 in the laminated state (S40) may include brazing the brazing filler 300 through melting.

The brazing may be performed at a temperature that is equal to or higher than 450° C., and preferably, at 780° ° C. to 900° C., and in order to heighten the bonding force during the brazing, top weighting or pressurization may be carried out.

As an example, in the brazing, a laminated body, in which the ceramic substrate 100 is laminated on the base plate 200 by inserting the lower electrode layer 130 into the recess groove 210 on which the brazing filler 300 is disposed, is prepared, and the laminated body may be disposed between an upper pressurization jig and a lower pressurization jig in a brazing furnace (not illustrated), and upper and lower surfaces of the laminated body can be pressurized.

Further, the laminated body may be disposed in the brazing furnace, and a weighting body may be disposed on an upper surface of the laminated body to pressurize the laminated body from above. In the brazing, the top weighting or pressurization is performed for void-free bonding.

Since the brazing does not require the vacuum bonding equipment like the usage of the solder preform, the process simplification becomes possible, and by performing the top weighting or pressurization, the porosity defect is prevented, the bonding strength is heightened, and thus the bonding reliability is heightened.

Through the brazing, the base plate 200 and the ceramic substrate 100 may be united in a body.

According to the above-described embodiment, the base plate 200 is composed of a single-layer structure. However, the base plate 200 may be composed of a multilayer structure to have a low thermal expansion coefficient (low CTE). As an example, the base plate 200 may be provided as a three-layer metal sheet in which a Cu metal sheet having a relatively high thermal expansion coefficient and high thermal conductivity is formed on upper and lower surfaces of a CuMo metal sheet having a relatively low thermal expansion coefficient. According to the base plate 200, the CuMo metal sheet can absorb the flexure of the Cu metal sheet, and through this, the flexure phenomenon that occurs due to the difference in the thermal expansion coefficients at a high temperature can be reduced.

As described above, in case that the base plate 200 is formed as a 3-layer bonding metal sheet structure of Cu/CuMo/Cu or AlSiC, it has the prominent bonding characteristic in bonding onto the ceramic substrate 100, and may have the thermal expansion coefficient of 6.8 to 12 ppm/K and the thermal conductivity of 220 to 280 W/m·K.

According to the present disclosure as described above, since the ceramic substrate 100 is brazed onto the base plate 200 in the laminated state through insertion of the lower electrode layer 130 of the ceramic substrate 100 into the recess groove 210 of the base plate 200, the bonding reliability is heightened, the flexure can be prevented, and the heat dissipation effect is heightened.

In particular, since the brazing does not require the vacuum bonding equipment like the usage of the solder preform in the related art, the process simplification becomes possible, and by performing the top weighting or pressurization, the porosity defect is prevented, the bonding strength is heightened, and thus the bonding reliability is heightened.

Further, since the brazing is performed in a state where the lower electrode layer 130 and the recess groove 210 are fitted in size, the space in which the bubbles occur can be removed during injection of the insulation gel, and the porosity defect can be prevented.

In addition, since the space 131 is formed through etching of a part of the lower electrode layer in the thickness direction, the volume ratio and the area ratio of the upper electrode layer 120 and the lower electrode layer 130 can be controlled to be within the specific range, and thus the flexure phenomenon occurring due to the volume difference can be suppressed.

Although it has been exemplarily explained that the above-described bonding structure of the ceramic substrate and the base plate is applied to the power module, it can be applied to various bonding structures requiring high reliability bonding.

Preferred embodiments of the present disclosure have been disclosed in the drawings and the description. Here, although specific terms have been used, this is merely for the purpose of explaining the present disclosure, but is not for limiting the meanings or limiting the scope of the present disclosure described in claims. Accordingly, it will be understood by those of ordinary skill in the art to which the present disclosure pertains that various modifications or other equivalent embodiments are possible therefrom. Accordingly, the authentic technical scope of the present disclosure should be determined by the technical ideas of the appended claims.

1. A power module comprising:
a ceramic substrate; and
a base plate bonded onto a lower part of the ceramic substrate,
wherein the ceramic substrate includes:
a ceramic base material;
an upper electrode layer formed on an upper surface of the ceramic base material; and
a lower electrode layer formed on a lower surface of the ceramic base material and separated into a plurality of areas, and
wherein the base plate has a plurality of recess grooves formed thereon to correspond to the lower electrode layer, and the lower electrode layer is inserted into the recess grooves.

2. The power module of claim 1, wherein the lower electrode layer is separated into the plurality of areas by a space formed by etching a part of the lower electrode layer in a thickness direction.

3. The power module of claim 1, wherein a volume ratio that is obtained by dividing a total volume of the upper electrode layer by a total volume of the lower electrode layer is 0.9 to 1.1.

4. The power module of claim 1, wherein thicknesses of the upper electrode layer and the lower electrode layer are equal to each other, and
wherein an area ratio that is obtained by dividing a total area of the upper electrode layer by a total area of the lower electrode layer is 0.9 to 1.1.

5. The power module of claim 1, comprising a brazing filler disposed between the lower electrode layer and the recess grooves, and configured to braze the ceramic substrate and the base plate.

6. The power module of claim 5, wherein the recess groove of the base plate is formed with a thickness that is equal to a sum of thicknesses of the lower electrode layer and the brazing filler.

7. A method for producing a power module comprising:
preparing an upper electrode layer and a lower electrode layer on upper and lower surfaces of a ceramic base material, and preparing a ceramic substrate on which the lower electrode layer is separated into a plurality of areas;
preparing a base plate having a recess groove formed thereon to correspond to the lower electrode layer;
inserting the lower electrode layer into the recess groove; and
bonding the ceramic substrate on the base plate in a laminated state.

8. The method of claim 7, wherein the preparing of the ceramic substrate comprises forming a space that is separated into the plurality of areas by etching a part of the lower electrode layer in a thickness direction.

9. The method of claim 8, wherein the forming of the space that is separated into the plurality of areas forms the space so that a volume ratio that is obtained by dividing a total volume of the upper electrode layer by a total volume of the lower electrode layer is 0.9 to 1.1.

10. The method of claim 8, wherein the forming of the space that is separated into the plurality of areas forms the space so that an area ratio that is obtained by dividing a total area of the upper electrode layer by a total area of the lower electrode layer is 0.9 to 1.1 in case that thicknesses of the upper electrode layer and the lower electrode layer are equal to each other.

11. The method of claim 7, wherein in the preparing of the base plate, the base plate is annealed to remove a thermal stress therefrom.

12. The method of claim 7, wherein the preparing of the base plate comprises disposing a brazing filler onto the recess groove.

13. The method of claim 12, wherein in the preparing of the base plate, the recess groove is formed by etching the base plate in a thickness direction, and
wherein a depth of the recess groove is equal to a sum of thicknesses of the lower electrode layer and the brazing filler.

14. The method of claim 12, wherein the disposing of the brazing filler disposes the brazing filler having a thickness that is equal to or larger than 5 μm and equal to or smaller than 100 μm onto the recess groove by any one method of paste application, foil attachment, and P-filler.

15. The method of claim 12, wherein the bonding of the ceramic substrate on the base plate in the laminated state comprises brazing the brazing filler through melting.

16. The method of claim 15, wherein the brazing is performed at 780° ° C. to 900° ° C., and top weighting or pressurization is carried out during the brazing.
